(19) United States
(12) Patent Application Publication
(10) Pub. No.: US 2026/0182386 A1
(43) Pub. Date: Jun. 25, 2026

(54) SEMICONDUCTOR DEVICE

(71) Applicant: Mitsubishi Electric Corporation, Tokyo (JP)

(72) Inventors: Kazutake KADOWAKI, Tokyo (JP); Hiroki SHIOTA, Tokyo (JP)

(73) Assignee: Mitsubishi Electric Corporation, Tokyo (JP)

(21) Appl. No.: 18/836,369

(22) PCT Filed: Mar. 17, 2022
(86) PCT No.: PCT/JP2022/012189

§ 371 Date: Aug. 7, 2024

(51) Int. Cl. H10W 42/20; H10W 76/10

(52) U.S. Cl. CPC H10W 42/265; H10W 76/10

(57) ABSTRACT

A semiconductor device includes: an insulating substrate; a pattern having a thin plate shape and made of metal, the pattern being formed on an upper surface of the insulating substrate; and a semiconductor chip joined to an upper surface of the pattern. A metal wire connected to the pattern at a plurality of connection points is provided above the pattern along an outer periphery of the pattern.

### TECHNICAL FIELD

The present disclosure relates to a semiconductor device.

### BACKGROUND ART

In a semiconductor device, an insulating substrate is joined to an upper surface of a grounded base board, and an electrode is formed at an upper surface of the insulating substrate. In this structure, an end of the electrode is likely to suffer dielectric breakdown due to electric field concentration. Accordingly, there is known a semiconductor device structure in which a second metal substrate having the same potential as the electrode is provided at a position symmetric with the base board as seen from the electrode so as to relax the maximum electric field, thus improving insulation performance (see, for example, Patent Document 1.).

### CITATION LIST

### Patent Document

Patent Document 1: Japanese Laid-Open Patent Publication No. 2003-386763

### SUMMARY OF THE INVENTION

### Problem to be Solved by the Invention

However, in the conventional semiconductor device, since the second metal substrate needs to be provided, it is difficult to achieve both of improvement in insulation performance and further reduction of the size of the semiconductor device.

The present disclosure has been made to solve the above problem, and an object of the present disclosure is to provide a semiconductor device having improved insulation performance and a reduced size.

### Means to Solve the Problem

A semiconductor device according to the present disclosure includes: an insulating substrate; a pattern having a thin plate shape and made of metal, the pattern being formed on an upper surface of the insulating substrate; and a semiconductor chip joined to an upper surface of the pattern. A metal wire connected to the pattern at a plurality of connection points is provided above the pattern along an outer periphery of the pattern.

Another semiconductor device according to the present disclosure includes: an insulating substrate; a pattern having a thin plate shape and made of metal, the pattern being formed on an upper surface of the insulating substrate; and a semiconductor chip joined to an upper surface of the pattern. A projection projecting upward of the pattern is provided along an outer periphery of the pattern.

### Effect of the Invention

The semiconductor device according to the present disclosure makes it possible to provide a semiconductor device having improved insulation performance and a reduced size.

### BRIEF DESCRIPTION OF THE DRAWINGS

FIG. 1 is a schematic sectional view of a semiconductor device according to embodiment 1.

FIG. 2 is a perspective view showing a major part of the semiconductor device according to embodiment 1.

FIG. 3 is a schematic sectional view of a major part of the semiconductor device according to embodiment 1 when cut in the vertical direction at a broken line A part in FIG. 2.

FIG. 4 is a schematic sectional view showing a major part of a semiconductor device according to embodiment 2.

FIG. 5 is a perspective view showing a major part of a semiconductor device according to embodiment 3.

FIG. 6 is a schematic sectional view of a major part of the semiconductor device according to embodiment 3 when cut in the vertical direction at a broken line B part in FIG. 5.

FIG. 7A to FIG. 7D are perspective views showing a placement process for wires on a pattern.

FIG. 8 is a schematic plan view showing one corner of a pattern according to embodiment 4.

FIG. 9 is a schematic plan view of a major part of the semiconductor device according to embodiment 4 and shows a corner of the pattern with wires attached thereto.

FIG. 10 is a schematic sectional view of a major part of a semiconductor device according to embodiment 5 and shows the vicinity of an outer periphery of a pattern.

FIG. 11 is a schematic sectional view of a semiconductor device according to embodiment 6.

FIG. 12 is a schematic sectional view showing the vicinity of an outer periphery of a pattern according to embodiment 6.

FIG. 13 is a schematic plan view showing the vicinity of a corner of the pattern according to embodiment 6.

FIG. 14 is a schematic plan view showing a modification of the pattern according to embodiment 6.

### DESCRIPTION OF EMBODIMENTS

### Embodiment 1

Hereinafter, a semiconductor device according to embodiment 1 will be described with reference to the drawings.

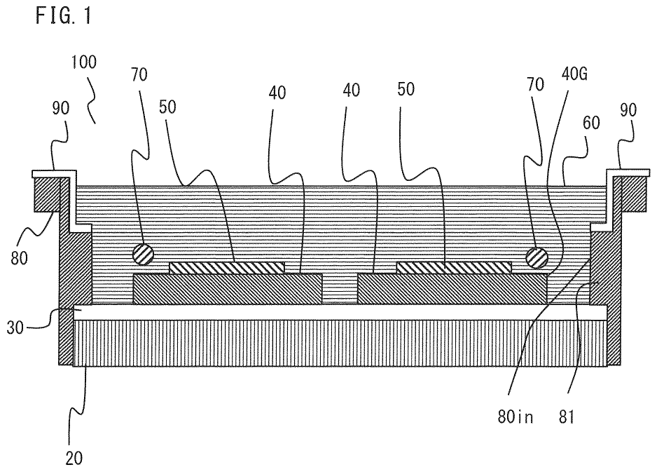

FIG. 1 is a schematic sectional view of a semiconductor device 100 according to embodiment 1.

As used herein, when an inner side or an outer side is mentioned, a center side of the semiconductor device 100 is the inner side, and the side opposite thereto is the outer side. When an up-down relationship is mentioned, a base board 20 side of the semiconductor device 100 is a lower side, and the side opposite thereto is an upper side.

The semiconductor device 100 includes the base board 20 having a substantially rectangular parallelepiped shape and made of metal, and an insulating substrate 30 having a thin plate shape and joined to an upper surface of the base board 20. A pattern 40 having a thin plate shape and made of metal is formed on another surface (upper surface) of the insulating substrate 30 that is not joined to the base board 20, and a semiconductor chip 50 having a thin plate shape is joined to an upper surface of the pattern 40. The insulating substrate 30 may be produced by shaping an insulating epoxy resin kneaded with an insulating filler into a thin plate shape, or as another example, the insulating substrate 30 may be produced using ceramic.

The semiconductor chip 50 is a power semiconductor element such as an insulated gate bipolar transistor, a power metal-oxide-semiconductor field-effect transistor (MOSFET), or a freewheeling diode (FWD), and may be formed from one kind or a combination of two or more kinds of the above examples. The semiconductor chip 50 may be formed at a silicon substrate, or may be formed at another semiconductor material such as silicon carbide or gallium nitride.

The semiconductor device 100 includes a connection terminal 90 to an external circuit, and a case 80 having a rectangular-frame-shaped cross-section. The case 80 has an engagement portion 81 protruding inward, at a middle part between the upper side and the lower side of an inner wall. The base board 20 and the insulating substrate 30 overlaid on the upper surface of the base board 20 are fitted to the inside of the case 80 such that an edge of the upper surface of the insulating substrate 30 contacts with the aforementioned engagement portion 81, thus closing one opening of the case 80. The insulating substrate 30 and the case 80 may be adhered to each other.

The connection terminal 90 is electrically connected to the pattern 40 and the semiconductor chip 50 via a metal conductor (not shown) so as to form a desired electric circuit.

The inside of the case 80 is filled with a sealing resin 60, which provides protection and electric insulation of members of the semiconductor chip 50 and the pattern 40. As the sealing resin 60, an epoxy resin kneaded with an insulating filler is typically used. However, the sealing resin 60 may be any solid having insulation property, and another example of an epoxy resin is silicone gel.

A metal wire 70 is provided above the pattern 40 along an outer periphery 40G of the pattern 40 opposed to an inner side surface 80in of the case 80. The wire 70 is connected to the pattern 40 at a plurality of locations. Therefore, the wire 70 is electrically at the same potential as the pattern 40. Examples of the material of the wire 70 include aluminum and copper, but any metal material may be used.

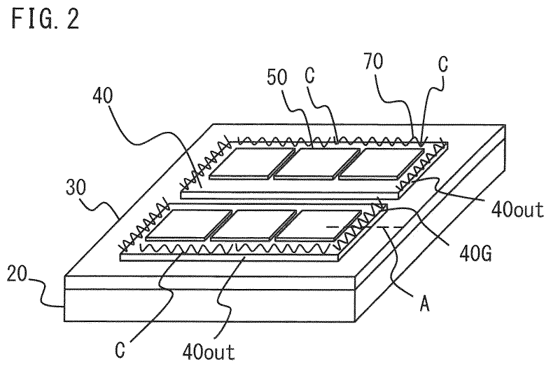

FIG. 2 is a perspective view showing a major part of the semiconductor device 100. In FIG. 2, the case 80, the sealing resin 60, and the connection terminal 90 are not shown. The wire 70 is provided above the pattern 40 along, of the outer periphery 40G of the pattern 40, a part where an outer side surface 40out of the pattern 40 is opposed to an inner side surface 80in of the case 80, and the wire 70 and the pattern 40 are electrically connected to each other at a plurality of locations as described above.

At the same pattern 40, a plurality of wires 7C may be provided as shown in FIG. 2, or only a single wire 70 may be provided continuously. Between connection points C between the wire 70 and the pattern 40, the wire 70 forms an arch-shaped wire loop, and the distance between the wire 70 and the pattern 40 is not greater than five times the diameter of the wire 70.

Among the connection points C between the wire 70 and the pattern 40, if the interval between the adjacent connection points C is too long, in a manufacturing process for the semiconductor device 100, the wire 70 is drawn together with the sealing resin 60 when the sealing resin 60 is injected, so that the wire 70 might deviate from a predetermined position. Therefore, typically, the connection points C are arranged at intervals of 5 mm or less. The intervals may be determined in accordance with the material of the sealing resin 60 and the injection method therefor so that the wire 70 will not be drawn.

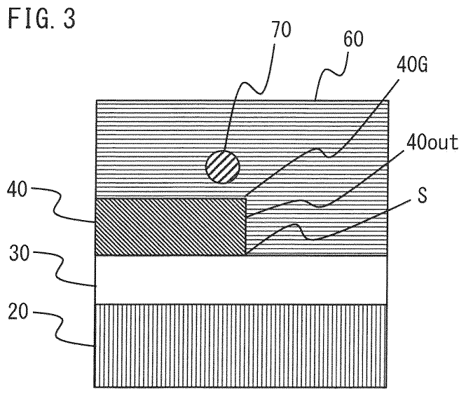

FIG. 3 is a schematic sectional view of a major part of the semiconductor device 300 when cut in the vertical direction at a broken line A part in FIG. 2. Next, with reference to FIG. 3, an effect of improving the insulation performance by the wire 70 will be described. In FIG. 3, the potential of the base board 20 is a ground potential, and high voltage is applied to the pattern 40 and the wire 70. Thus, an electric field concentrates on a joining end S between the insulating substrate 30 and the pattern 40.

Furthermore, what is worse, the joining end S is a part where a void is likely to remain when the sealing resin 60 is cured or separation is likely to occur between the sealing resin 60 and the insulating substrate 30, and thus is a weak part in terms of insulation.

Therefore, by relaxing the electric field at the joining end S, it is possible to improve insulation performance of the semiconductor device 100. Here, the wire 70 having the same potential as the pattern 40 is provided above the pattern 40 along the outer periphery 40G of the pattern 40, whereby, as compared to a case where the wire 70 is not present, an electric field distribution on the outer side surface 40out of the pattern 40 can be flattened and thus the electric field at the joining end S can be relaxed.

The area where the wire 70 is provided is an area filled with the sealing resin 60 also in a conventional structure (in which the wire 70 is not used), and therefore, providing the wire 70 does not require any size increase in the semiconductor device 100. In addition, owing to provision of the electric field relaxing effect, it becomes possible to reduce an area where the pattern 40 is not provided at an end of the insulating substrate 30 as compared to a conventional structure, whereby the size of the semiconductor device 100 can be further reduced.

The semiconductor device 100 according to embodiment 1 makes it possible to provide a semiconductor device having improved insulation performance and a reduced size.

### Embodiment 2

Hereinafter, a semiconductor device according to embodiment 2 will be described focusing on difference from embodiment 1.

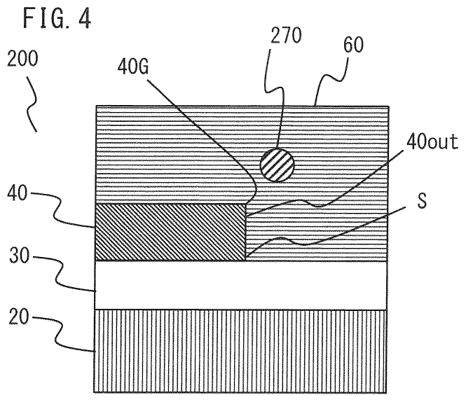

FIG. 4 is a schematic sectional view showing a major part of the semiconductor device 200. This is a schematic sectional view showing the vicinity of the outer periphery 40G of the pattern 40 and corresponds to FIG. 3 in embodiment 1. Along the outer periphery 40G of the pattern 40 opposed to the inner side surface 80in of the case 80, a wire 270 is connected to the upper surface of the pattern 40 at the connection points C as in embodiment 1. Between the adjacent connection points C, the wire 270 curves so as to protrude outward from an area above the pattern 40 toward the end side of the insulating substrate 30. With this structure, in an area directly under the protruding part of the wire 270, the electric field distribution on the outer side surface 40out of the pattern 40 can be further flattened and the electric field at the joining end S is relaxed, whereby insulation of the semiconductor device 200 can be further enhanced. In order to configure the wire 270 as described above, the manufacturing process for the semiconductor device 100 includes a step of connecting a wire along the outer periphery 40G of the pattern 40 and a step of curving the wire to a predetermined position.

### Embodiment 3

Hereinafter, a semiconductor device according to embodiment 3 will be described focusing on difference from embodiment 2.

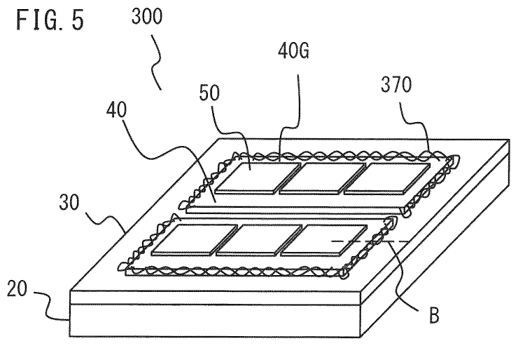

FIG. 5 is a perspective view showing a major part of the semiconductor device 300. In FIG. 5, the case 80, the sealing resin 60, and the connection terminal 90 are not shown.

A wire 370 is connected to the upper surface of the pattern 40 at a plurality of locations along the outer periphery 40G of the pattern 40 opposed to the inner side surface 80in of the case 80. Two wires 370 are connected on each side of the outer periphery 40G of the pattern 40 to which the wires 370 are attached, and the two wires 370 cross each other.

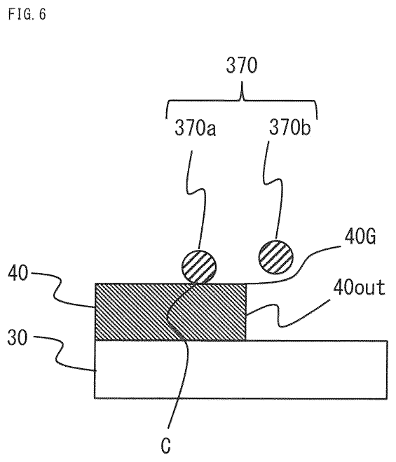

FIG. 6 is a schematic sectional view of a major part of the semiconductor device 300 when cut in the vertical direction at a broken line B part in FIG. 5.

Regarding the two wires 370 connected to each side of the pattern 40, at a part where one wire 370a is connected to the pattern 40 at the connection point C in the cross-section in FIG. 6, another wire 370b is located so as to protrude in the horizontal direction of the insulating substrate 30 and thus the wire 370b is provided so as to curve outward.

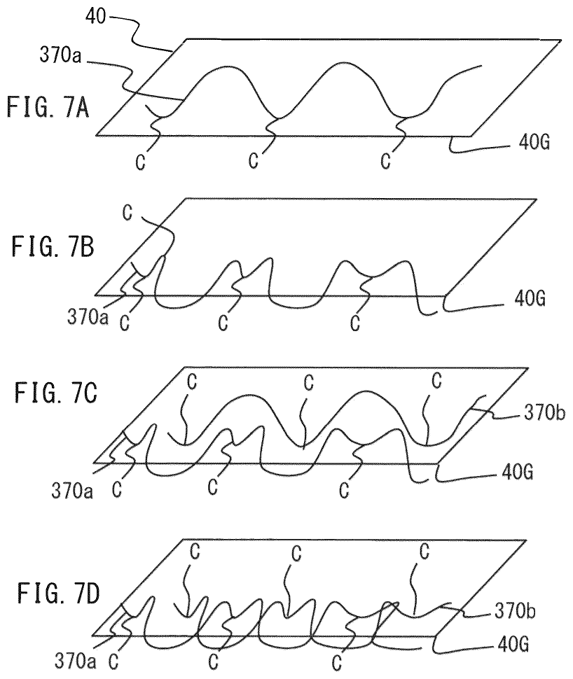

FIG. 7A to FIG. 7D are perspective views showing a placement process for the wires 370 on the pattern 40. First, as shown in FIG. 7A, a first wire 370a is connected at a plurality of connection points C along the outer periphery 40G of the pattern 40. The intervals between the connection points C are set so that wire loops having predetermined heights are formed. Next, as shown in FIG. 7B, the first wire 370a is curved to predetermined positions so as to protrude outward from an end of the pattern 40.

Next, as shown in FIG. 7C, a second wire 370b is connected to the pattern 40. At this time, the second wire 370b is connected to the pattern 40 such that each connection point C of the newly connected wire 370b is located, in the outer periphery direction of the pattern 40, between the two adjacent connection points C between the previously provided first wire 370a and the pattern 40. Next, as shown in FIG. 170, the second wire 370b is curved so as to protrude outward from the outer periphery 40G of the pattern 40 in the same manner as the first wire 370a.

In the semiconductor device 300 according to embodiment 3, an area where the electric field distribution can be flattened over the entire outer side surface 40out of the pattern 40 can be ensured also in an area directly under the curved part of the wire 370b, whereby the semiconductor device 300 having a relaxed electric field at the joining end S and having further enhanced insulation can be provided.

### Embodiment 4

Hereinafter, a semiconductor device according to embodiment 4 will be described focusing on difference from embodiments 1 to 3.

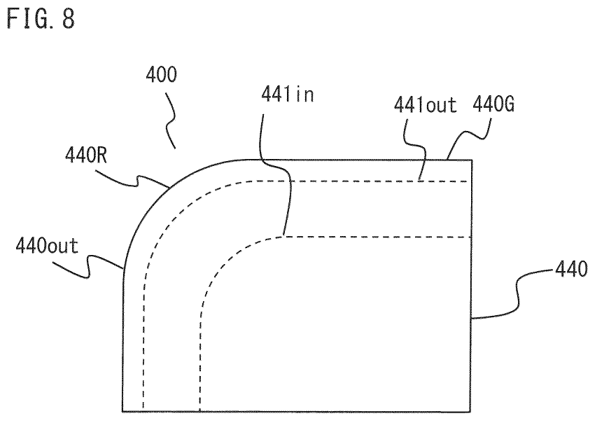

FIG. 8 is a schematic plan view showing one corner of a pattern 440.

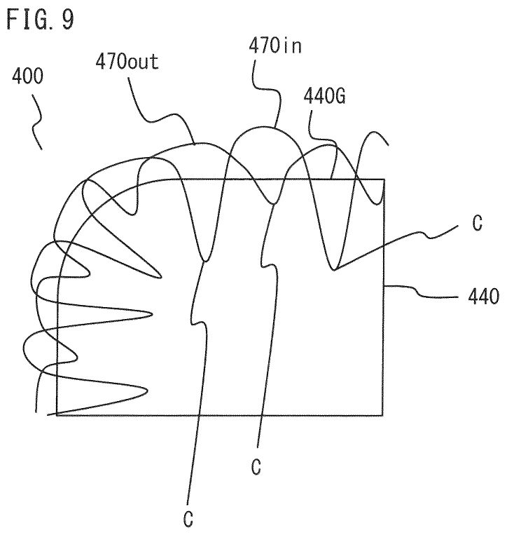

FIG. 9 is a schematic plan view of a major part of a semiconductor device 400 and shows a corner of the pattern 440 to which wires 470in, 470out are attached.

As shown in FIG. 8, four corners of an outer periphery 440G of the pattern 440 are rounded in the same manner and two wire connection portions 441in, 441out are set in approximately parallel along the outer periphery 440G including rounded portions 440R. The shown wire connection portions 441in, 441out are lines connecting the respective connection points C of the two wires 470in, 470out.

Of the two wires 470in, 470out connected along the outer periphery 440G of the pattern 440, the wire 470out on the outer side is provided so as to have the connection points C only on the wire connection portion 441out on the outer side, and the wire 470in on the inner side is provided so as to have the connection points C only on the wire connection portion 441in on the inner side.

The process for placing the wires 470in, 470out includes a step of connecting a first wire 470out to the wire connection portion 441out which is closer to the outer periphery 440G of the pattern 440, a step of curving the wire 470out to predetermined positions outward of the pattern 440, a step of connecting a second wire 470in to the wire connection portion 441in on the inner side, and a step of curving the second wire 470in outward of the pattern 440.

In the semiconductor device 400 according to embodiment 4, the area where the electric field distribution on the outer side surface 440out of the pattern 440 can be flattened in the area directly under the curved parts of the wires 470in, 470out, can be extended over the entire outer periphery 440G of the pattern 440, whereby the semiconductor device 400 having a relaxed electric field at the joining end S and having further enhanced insulation can be provided. Furthermore, since two wire connection portions 441out, 441in are provided in parallel along the rounded portion 440R of the outer periphery 440G of the pattern 440, the first wire 470out and the second wire 470in do not interfere with each other when the second wire 470in is connected to the pattern 440. Thus, a more reliable semiconductor device 400 and a more reliable manufacturing method therefor can be obtained.

### Embodiment 5

Hereinafter, a semiconductor device according to embodiment 5 will be described focusing on difference from embodiments 1 to 4.

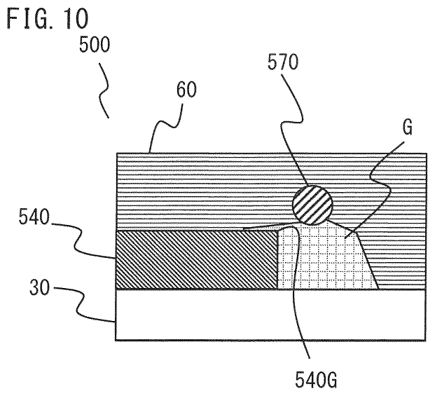

FIG. 10 is a schematic sectional view of a major part of a semiconductor device 500 and shows the vicinity of an outer periphery 540G of a pattern 540. A wire 570 is connected along the outer periphery 540G of the pattern 540, and the wire 570 protrudes outward of the pattern 540. An insulation coating G is provided between the wire 570 and the insulating substrate 30.

The insulation coating G is resin which is curable by some means after being applied, and is, for example, silicone rubber. However, without limitation to silicone rubber, any material having insulation property and curing property may be used. Regarding curing means, curing by heat as in silicone rubber may be adopted, or as another example, curing by an action of ultraviolet rays may be adopted. The curing means is not particularly limited.

A placement process for the wire 570 includes a step of applying the insulation coating G on the insulating substrate 30, a step of curing the insulation coating G, and a step of connecting the wire 570 to the pattern 540. The structure in which the wire 70 is curved as described in embodiment 2, the structure in which two wires 270 are provided so as to cross each other as described in embodiment 3, and the structure in which connection portions for two wires are provided apart from each other in parallel as described in embodiment 4, may be combined as appropriate in accordance with requirements in designing.

The semiconductor device 500 according to embodiment 5 makes it possible to avoid such a trouble that, in a step of curving the wire 570 and in a step of injecting and curing the sealing resin 60, the wire 570 collapses to the insulating substrate 30 side more than necessary and the effect of relaxing an electric field is not obtained. Thus, the semiconductor device 500 having more enhanced reliability can be provided.

### Embodiment 6

Hereinafter, a semiconductor device according to embodiment 6 will be described focusing on difference from embodiments 1 to 5.

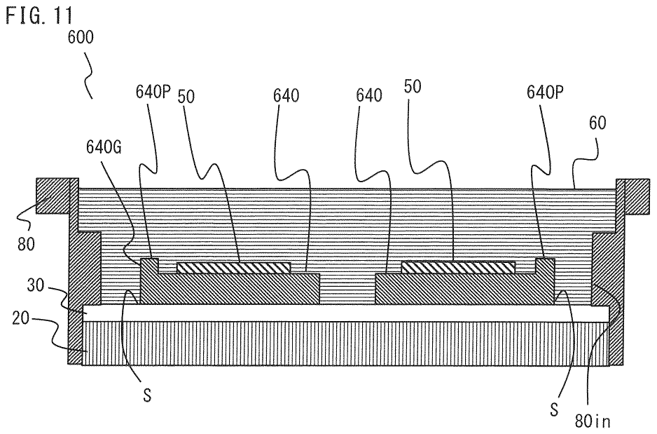

FIG. 11 is a schematic sectional view of a semiconductor or device 600 according to embodiment 6.

Along an outer periphery 640G of a pattern 640 opposed to the inner side surface 80in of the case 80, a metal projection 640P projecting so that the thickness of the pattern 640 increases upward of the insulating substrate 30, is provided. The projection 640P and the pattern 640 are electrically connected to each other so as to have the same potential. The projection 640P may be formed by providing a thick pattern 640 on the insulating substrate 30 and then cutting a part other than the projection 640P, or by separately joining a metal member to a thin pattern 640.

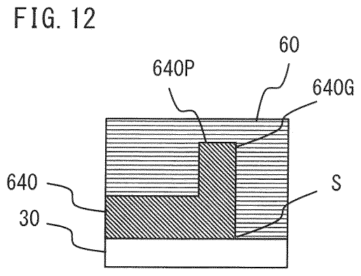

FIG. 12 is a schematic sectional view showing the vicinity of the outer periphery 640G of the pattern 640.

The projection 640P is provided only at an outer periphery part of the pattern 640 opposed to the inner side surface 80in of the case 80, whereby it is possible to relax an electric field at the joining end S between the insulating substrate 30 and the pattern 640 without increasing the thickness of the entire pattern 640.

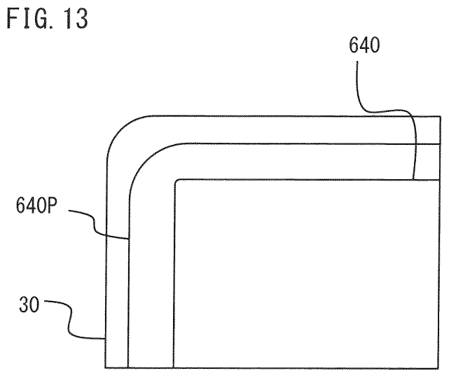

FIG. 13 is a schematic plan view showing the vicinity of a corner of the pattern 640.

The projection 640P is formed along the outer periphery 640G of the pattern 640 opposed to the inner side surface 80in of the case 80. Thus, the area where the electric field is relaxed can be provided over the entire periphery of the insulating substrate 30. Accordingly, the semiconductor device 600 having further enhanced insulation can be provided.

With the pattern 640 configured as described above, as another advantage, the thickness of the pattern 640 can be decreased in a central area of the pattern 640 which does not influence electric field relaxation, and thus it becomes possible to reduce the thermal resistance of the pattern 640 in releasing heat generated in the semiconductor chip 50 to the base board 20.

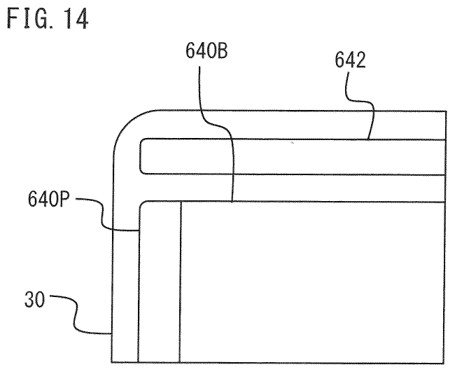

FIG. 14 is a schematic plan view showing a modification of embodiment 6 and shows a pattern 640B different from that in FIG. 13.

At an end of the insulating substrate 30, a narrow-width pattern where the semiconductor chip 50 is not mounted may be provided for a circuit configuration reason. As in this case, it is assumed that a projection cannot be provided because the pattern width is narrow. However, in such a case, the entirety of the above narrow-width pattern may be increased in thickness, to be formed as a thick pattern 642, which may be combined with the pattern 640B having the projection 640P. The thickness of the thick pattern 642 may be the same as a thickness of a part of the pattern 640B where the projection 640P is provided.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

100, 200, 300, 400, 500, 600 semiconductor device
20 base board
30 insulating substrate
40, 440, 540, 640, 6403 pattern
40out, 440out outer side surface
40G, 440G, 540G, 640G outer periphery
440R rounded portion
441in, 441out wire connection portion
640P projection
642 thick pattern
50 semiconductor chip
60 sealing resin
70, 270, 370, 370a, 370b, 470in, 470out, 570 wire
80 case
80in inner side surface
81 engagement portion
90 connection terminal
A, B broken line
C connection point
G insulation coating
S joining end

1. A semiconductor device comprising:
an insulating substrate;
a pattern having a thin plate shape and made of metal, the pattern being formed on an upper surface of the insulating substrate;
a semiconductor chip joined to an upper surface of the pattern; and
a metal wire connected to the pattern at a plurality of connection points is provided above the pattern along an outer periphery of the pattern, wherein
between the connection points adjacent to each other, the wire curves so as to protrude outward from an area above the pattern toward an end side of the insulating substrate.

2. (canceled)

3. The semiconductor device according to claim 1, wherein
the wire comprises two wires, and
between adjacent two of the connection points of one of the wires, each of the connection points of the other wire is located.

4. The semiconductor device according to claim 3, wherein
a line connecting the connection points of one of the wires and a line connecting the connection points of the other wire are arranged in parallel along the outer periphery of the pattern.

5. The semiconductor device according to claim 4, wherein
the pattern has a rounded corner.

6. The semiconductor device according to claim 1, wherein
an insulation coating made of resin having insulation property and curing property is provided between the insulating substrate and a part, of the wire, that protrudes outward from the area above the pattern toward the end side of the insulating substrate.

7. The semiconductor device according to claim 1, wherein
the wire forms an arch-shaped wire loop.

8. The semiconductor device according to claim 1, comprising:
a case; and
a base board provided inside the case so as to close one opening of the case, wherein
the insulating substrate is overlaid on an upper surface of the base board, and the wire is provided along the outer periphery of the pattern opposed to an inner side surface of the case.

9.-11. (canceled)

12. The semiconductor device according to claim 3, wherein
an insulation coating made of resin having insulation property and curing property is provided between the insulating substrate and a part, of the wire, that protrudes outward from the area above the pattern toward the end side of the insulating substrate.

13. The semiconductor device according to claim 4, wherein
an insulation coating made of resin having insulation property and curing property is provided between the insulating substrate and a part, of the wire, that protrudes outward from the area above the pattern toward the end side of the insulating substrate.

14. The semiconductor device according to claim 5, wherein
an insulation coating made of resin having insulation property and curing property is provided between the insulating substrate and a part, of the wire, that protrudes outward from the area above the pattern toward the end side of the insulating substrate.

15. The semiconductor device according to claim 3, wherein
the wire forms an arch-shaped wire loop.

16. The semiconductor device according to claim 4, wherein
the wire forms an arch-shaped wire loop.

17. The semiconductor device according to claim 5, wherein
the wire forms an arch-shaped wire loop.

18. The semiconductor device according to claim 6, wherein
the wire forms an arch-shaped wire loop.

19. The semiconductor device according to claim 3, comprising:
a case; and
a base board provided inside the case so as to close one opening of the case, wherein
the insulating substrate is overlaid on an upper surface of the base board, and the wire is provided along the outer periphery of the pattern opposed to an inner side surface of the case.

20. The semiconductor device according to claim 4, comprising:
a case; and
a base board provided inside the case so as to close one opening of the case, wherein
the insulating substrate is overlaid on an upper surface of the base board, and the wire is provided along the outer periphery of the pattern opposed to an inner side surface of the case.

21. The semiconductor device according to claim 5, comprising:
a case; and
a base board provided inside the case so as to close one opening of the case, wherein
the insulating substrate is overlaid on an upper surface of the base board, and the wire is provided along the outer periphery of the pattern opposed to an inner side surface of the case.

22. The semiconductor device according to claim 6, comprising:
a case; and
a base board provided inside the case so as to close one opening of the case, wherein
the insulating substrate is overlaid on an upper surface of the base board, and the wire is provided along the outer periphery of the pattern opposed to an inner side surface of the case.

23. The semiconductor device according to claim 7, comprising:
a case; and
a base board provided inside the case so as to close one opening of the case, wherein
the insulating substrate is overlaid on an upper surface of the base board, and the wire is provided along the outer periphery of the pattern opposed to an inner side surface of the case.
